(19) United States
(12) Patent Application Publication
(10) Pub. No.: US 2023/0056629 A1
(43) Pub. Date: Feb. 23, 2023

(54) CONTACT PADS-BASED CHASSIS TYPE DETECTION

(71) Applicant: HEWLETT-PACKARD DEVELOPMENT COMPANY, L.P., Spring, TX (US)

(72) Inventors: Hsin-Tso Lin, Taipei City (TW); Po Cheng Liao, Taipei City (TW); Chien-Hao Lu, Taipei City (TW)

(73) Assignee: HEWLETT-PACKARD DEVELOPMENT COMPANY, L.P., Spring, TX (US)

(21) Appl. No.: 17/796,856

(22) PCT Filed: Jan. 31, 2020
(86) PCT No.: PCT/US2020/016266

§ 371 Date: Aug. 1, 2022

(51) Int. Cl. G06F 1/18; G06F 1/20

(52) U.S. Cl. CPC G06F 1/184; G06F 1/206

(57) ABSTRACT

In one example, a computing device may include a circuit board having a contact pad disposed at an edge of the circuit board, and a chassis in which the circuit board is installed. The chassis may include a circuit board holder to engage the edge of the circuit board to retain the circuit board in a defined position relative to the chassis. The circuit board holder may be grounded. Further, the computing device may include a controller to receive a signal from the contact pad, the signal indicative of a presence of the circuit board holder contacting the contact pad. Furthermore, the controller may detect a form factor type of the chassis based on the received signal.

### BACKGROUND

Processor boards, such as printed circuit boards (PCBs) with components mounted thereon referred to as a printed circuit assembly (PCA), are mounted to the chassis of various electronic devices. In the PC world, it may be common for one PCA to be used in multiple mechanical form factors (i.e., multiple different models of computing devices). For instance, a single motherboard could fit in both a tower and a desktop enclosure. However, the different form factors might have different thermal profiles with different fan speed curves. In addition, one form factor may expose different motherboard input/output (I/O) ports or pins than another. Other parameters likewise might vary with form factor.

### BRIEF DESCRIPTION OF THE DRAWINGS

Examples are described in the following detailed description and in reference to the drawings, in which:

FIG. 1A is a block diagram of an example computing device, illustrating a circuit board holder on a chassis having a form factor mating with a contact pad on a circuit board;

FIG. 1B illustrates a partial isometric view of the example chassis of FIG. 1A, illustrating an example structure of the circuit board holder;

FIG. 1C illustrates a cross sectional schematic-view of the example chassis of FIG. 1A, depicting multiple circuit board holders;

FIG. 1D is a block diagram of the example computing device of FIG. 1A, depicting additional features;

FIG. 2A is a block diagram of an example computing device, illustrating a chassis detection circuit and a controller to detect a chassis type based on received signals;

FIG. 2B is a schematic view of the example computing device of FIG. 2A, depicting an example installation of the circuit board within the chassis;

FIG. 2C is a schematic view of the example computing device of FIG. 2A, depicting another example installation of the circuit board within the chassis;

FIG. 2D is a block diagram of the example computing device of FIG. 2A, depicting additional features;

FIG. 3 is a block diagram of an example computing device including a non-transitory machine-readable storage medium, storing instructions to control an operating parameter of the computing device;

FIG. 4 illustrates a block diagram of an example circuit board having first and second contact pads engaging with different circuit board holders on different chassis types;

FIG. 5A illustrates a schematic representation of an example circuit board having contact pads, with different contact pads engaging with circuit board holders on different chassis types;

FIG. 5B illustrates a schematic representation of another example circuit board having contact pads, with different contact pads engaging with a pair of circuit board holders on different chassis types; and

FIG. 5C illustrates a block diagram of the example circuit board of FIG. 5B, depicting contact pads engaging with different circuit board holders on different chassis types.

### DETAILED DESCRIPTION

In personal computing systems, different types of computing devices (e.g., two different models of servers) may be fitted with a “standardized” circuit board which includes a system processor and a memory. Further, the memory of the various types of computing devices may be loaded with the same programs, firmware, and basic input/output system (BIOS) code. Thus, the circuit board for various types (i.e., form factor types) of computing devices can be made by a single manufacturing process. However, different types of computing devices may have different thermal profiles with different optimal fan speed curves. In addition, one form factor might expose different circuit board input/output (I/O) ports or pins than another. Other parameters likewise might vary with the form factor.

One problem with such an approach is how an operating system and/or a controller determines the type of chassis and/or computing device in which the circuit board has been installed. In some examples, a manually set jumper or switch may be used to indicate the computing device type. However, such jumpers may not be correctly set during manufacture or may become dislodged during the manufacture or shipping of the computing device,

In some other examples, the memory of the circuit board may be programmed to account for the form factor in which the motherboard is to be installed, However, programming the memory may lock the motherboard to the form factor that is programmed in the memory until and unless the memory is reprogrammed, which may involve significant programming skills and may not be user-friendly, Also, the memory may have to be programmed correctly, and in some cases the location of the form factor type in memory can be accidentally or maliciously erased. In addition, a replacement circuit board may have to be updated manually.

Examples described herein may provide a circuit board (e.g., a printed circuit board (PCB), a printed circuit assembly (PCA), a motherboard, and the like) that detects a chassis type of a computing device in which the circuit board is installed. Examples described herein may enable the circuit board to detect the chassis type of the computing device by utilizing circuit board holders that are used to align and/or retain the circuit board in an aligned orientation within the chassis.

In the following description, for purposes of explanation, numerous specific details are set forth in order to provide a thorough understanding of the present techniques. However, the present apparatuses, devices, and systems may be practiced without these specific details, Reference in the specification to “an example” or similar language means that a particular feature, structure, or characteristic described is included in at least that one example, but not necessarily in other examples,

In one example, a computing device may include a circuit board having a contact pad disposed at an edge of the circuit board. Further, the computing device may include a chassis in which the circuit board is installed. The chassis may include a circuit board holder to engage the edge of the circuit board to retain the circuit board in a defined position relative to the chassis. The circuit board holder may be grounded. For example, different chassis may have circuit board holders located at different positions to assemble the circuit board in a correct location. The number and/or chassis locations of the circuit board holders can be unique to a form factor type of the chassis. Furthermore, the computing device may include a controller to receive a signal from the contact pad and detect a form factor type of the chassis based on the received signal. The signal may be indicative of a contact between the circuit board holder and the contact pad.

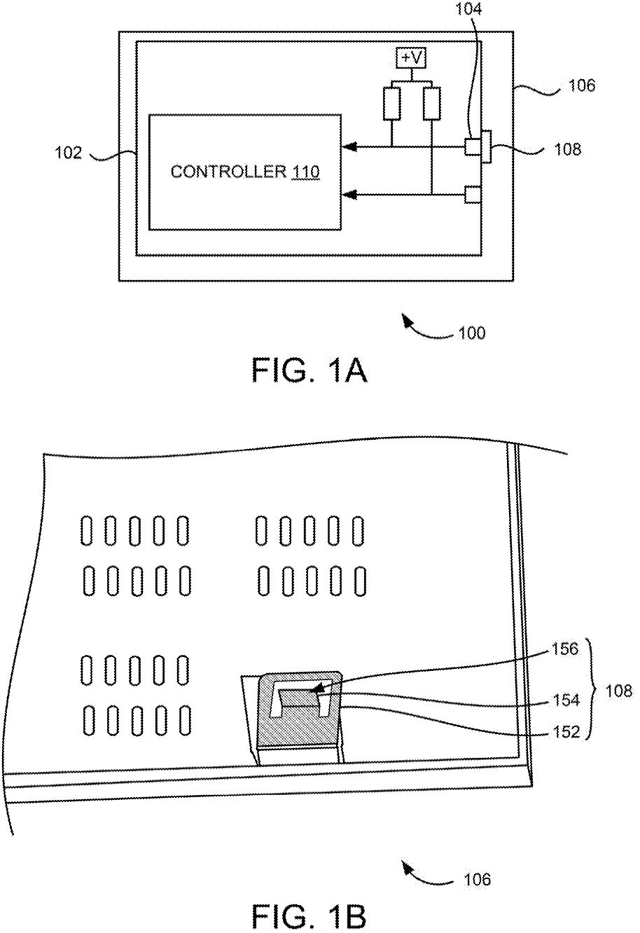

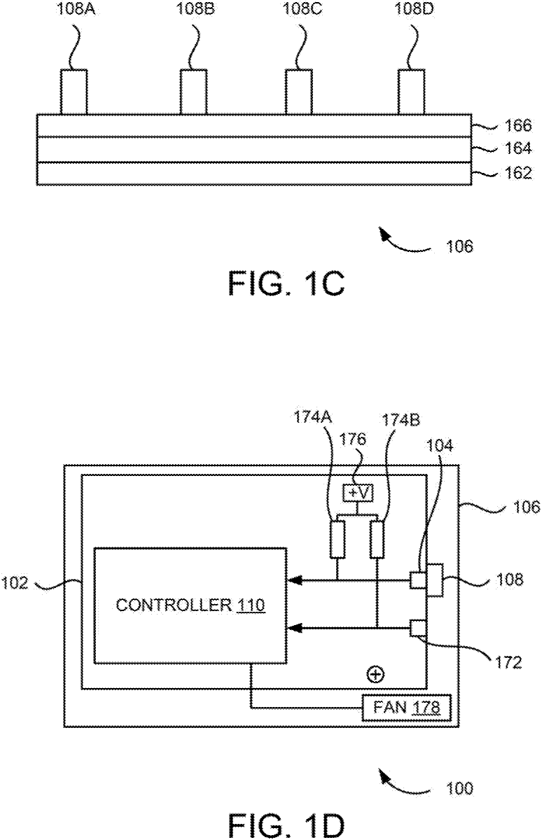

Turning now to the figures, FIG. 1A is a block diagram of an example computing device 100, illustrating a circuit board holder 108 on a chassis 106 having a form factor mating with a contact pad 104 on a circuit board 102. Example computing device 100 may include a mainframe, minicomputer, workstation, server, personal computer (PC), internet terminal, notebook, embedded system, or the like. Example PC may include desktop, floor standing, tower, or portable versions. Example circuit board 102 may be a motherboard, a PCA, or the like.

Example computing device 100 may include circuit board 102 having contact pad 104 disposed at an edge of circuit board 102. Example contact pad 104 may be a copper pad. Further, computing device 100 may include chassis 106 in which circuit board 102 may be installed. Furthermore, chassis 106 may include circuit board holder 108 to engage the edge of circuit board 102 to retain circuit board 102 in a defined position relative to chassis 106. For example, circuit board holder 108 may be grounded,

In one example, circuit board holder 108 may refer to a structure that can be used to align circuit board 102 within chassis 106 (i.e., placing circuit board 102 in an aligned orientation within chassis 106) and/or a structure that can be used to retain circuit board 102 in an aligned orientation within chassis 106. For example, different chassis may have circuit board holders located at different positions to assemble circuit board 102 in an aligned orientation. The number and/or chassis locations of the circuit board holders can be unique to a form factor type of chassis 106.

Furthermore, computing device 100 may include a controller 110. In one example, controller 110 may be disposed on circuit board 102 and communicatively coupled to system components of computing device 100. Example controller 110 may be an embedded controller, which may be implemented in hardware, machine-readable instructions, or a combination thereof. For example, controller 110 may be implemented as an engine or module including any combination of hardware and programming to implement the functionalities described herein, For example, controller 110 can be implemented with a microcontroller, an application-specific integrated circuit (ASIC), a field programmable gate array (FPGA), or the like. The functions of controller 110 may also be implemented by a processor. In examples described herein, the processor may include, for example, one processor or multiple processors included in a single device or distributed across multiple devices.

During operation, controller 110 may receive a signal from contact pad 104. The signal may be indicative of a contact between circuit board holder 108 and contact pad 104. Further, controller 110 may detect the form factor type of chassis 106 based on the received signal. Furthermore, controller 110 may control a parameter of computing device 100 that is dependent on the form factor type of chassis 106.

FIG. 1B illustrates a partial isometric view of example chassis 106 of FIG. 1A, illustrating an example structure of circuit board holder 108. Similarly named elements of FIG. 1B may be similar in function and/or structure to elements described in FIG. 1A. As shown in FIG. 1B, circuit board holder 108 may include a guide member 152 extending perpendicularly from chassis 106 to guide circuit board 102 (e.g., as shown in FIG. 1A) into the defined position while engaging a side surface of circuit board 102.

Further, circuit board holder 108 may include a retaining member 154 extending perpendicularly from guide member 152. In one example, retaining member 154 may include an exposed surface 156 on which a lower surface of the edge of circuit board 102 rests when circuit board 102 is installed onto chassis 106. In one example, guide member 152 may align circuit board 102 within chassis 106 in an aligned orientation and retaining member 154 may hold circuit board 102 parallel to a base of chassis 106. Upon placing circuit board 102 on retaining member 154, appropriate connections, both electrical and mechanical, may be made between circuit board 102 and various elements of chassis 106, and circuit board 102 may be retained in place with screws, clamps, springs clips, and/or other fastening components.

In one example, contact pad 104 (e.g., as shown in FIG. 1A) may be disposed on the side surface of circuit board 102 such that contact pad 104 may abut against guide member 152 when circuit board 102 is installed onto chassis 106. In another example, contact pad 104 may be disposed on a bottom surface at the edge of circuit board 102 such that contact pad 104 may abut against exposed surface 156 of retaining member 154 when circuit board 102 is installed onto chassis 106. In yet another example, contact pad 104 may be disposed on the side surface of circuit board 102 and extends towards the bottom surface such that contact pad 104 may abut against guide member 152 and retaining member 154 when circuit board 102 is installed onto chassis 106.

FIG. 1C illustrates a cross sectional schematic-view of example chassis 106, depicting multiple circuit board holders 108A-108D. Similarly named elements of FIG. 1C may be similar in function and/or structure to elements described in FIG. 1A. As shown in FIG. 1C, chassis 106 may include a metal layer 162, a plastic layer 164 (e.g., an insulating layer) disposed on metal layer 162, and a metal layer 166 disposed on plastic layer 164. Metal layer 166 may be grounded, Further, circuit board holders 108A-108D may be formed at different locations on metal layer 166 to assemble circuit board 102 (e.g., as shown in FIG. 1A) in the defined location.

As shown in FIG. 1C, circuit board holders 108A-108D may be disposed on chassis 106. In one example, circuit board holders 108A-108D may be connected to chassis 106 by a mounting screw. In another example, circuit board holders 108A-108D may be formed integrally with metal layer 166 of chassis 106.

FIG. 1D is a block diagram of example computing device 100 of FIG. 1A, depicting additional features. Similarly named elements of FIG. 1D may be similar in function and/or structure to elements described in FIG. 1A. As shown in FIG. 1D, computing device 100 may include pull up resistors 174A and 174B, each having a first end electrically coupled to a voltage source 176 and a second end electrically coupled to a respective one of contact pads 104 and 172. The signal may depend on a voltage level of the second end. Contact pads 104 and 172 may also be connected to controller 110.

As shown in FIG. 1D, contact pads 104 and 172 may be connected to voltage source 176 through resistors 174A and 174B, respectively. Also, contact pads 104 and 172 may be connected to respective general-purpose input output (GPIO) ports of controller 110. In the example shown in FIG. 1D, circuit board holder 108 may be on one type of chassis form factor and abut against contact pad 104 when circuit board 102 is installed onto chassis 106. In another example, circuit board holder 108 may be arranged at a different location on a second type of chassis form factor to mate with contact pad 172 on circuit board 102. Thus, when circuit board holder 108 abuts a contact pad (e.g., 104A or 172), the contact pad may be grounded, and otherwise the contact pad may not be grounded, In this way, the signals generated by contact pads 108 and 172 and sent to controller 110 may depend on which pad or pads are engaged by circuit board holder 108 and can be used to detect the form factor type of chassis 106.

Further, controller 110 may control a speed of a cooling fan 178 (or a type of input/output structure and/or protocol) on chassis 106, as appropriate for the detected form factor type of chassis 106 in which circuit board 102 is installed.

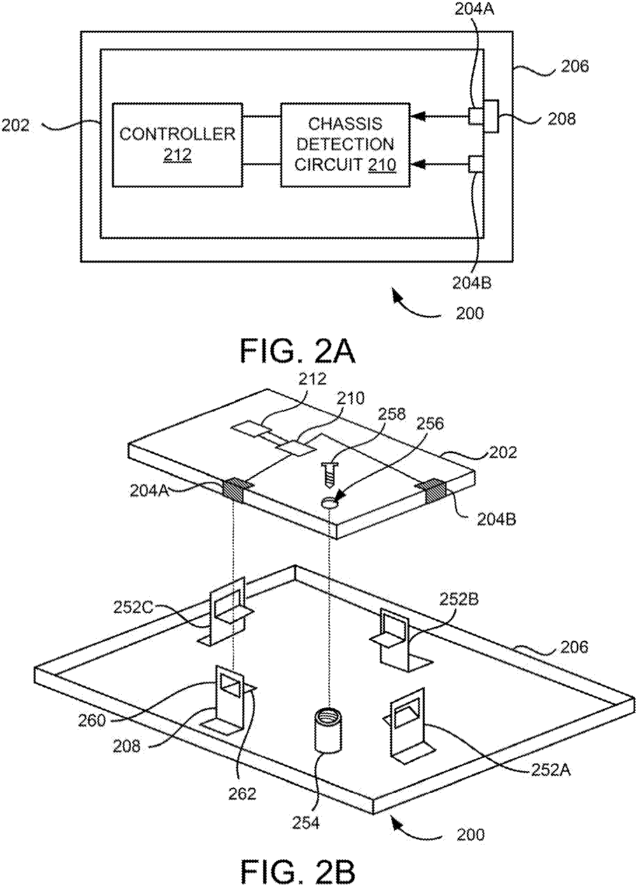

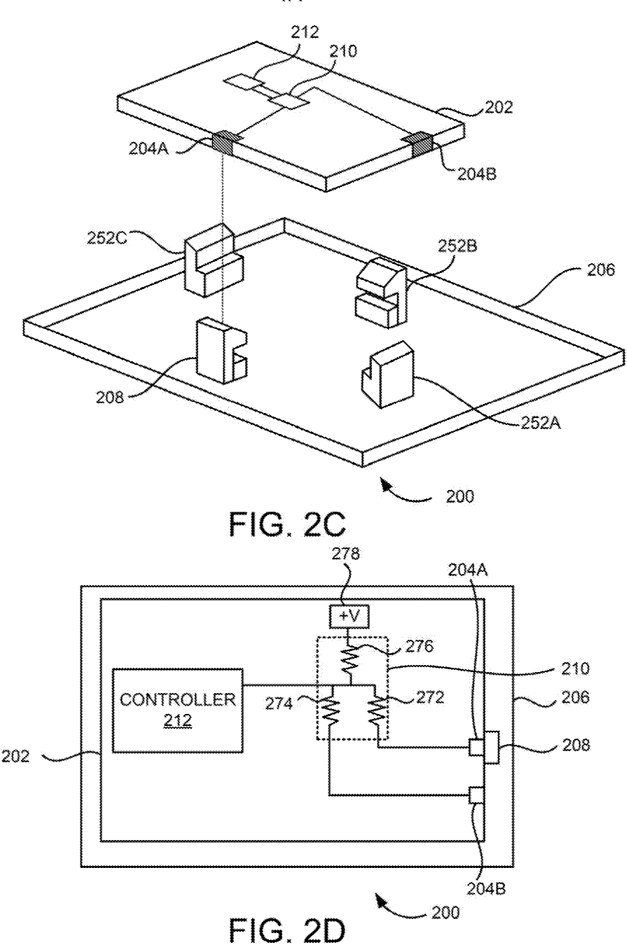

FIG. 2A is a block diagram of an example computing device 200, illustrating a chassis detection circuit 210 and a controller 212 to detect a chassis type based on received signals. Computing device 200 may include a circuit board 202 having a first contact pad 204A and a second contact pad 2048 disposed at an edge of circuit board 202. Further, computing device 200 may include a chassis 206 in which circuit board 202 is installed, In one example, chassis 206 may be of a chassis type. Further, chassis 206 may include a circuit board holder 208 to hold circuit board 202 in a defined position relative to chassis 206. In one example, circuit board holder 208 may be grounded (e.g., connected to a ground pin).

Further, computing device 200 may include chassis detection circuit 210 to generate a first signal and a second signal when circuit board 202 is engaged with chassis 206. The first and second signals may be indicative of an electrical contact between grounded circuit board holder 208 and first contact pad 204A or second contact pad 204B.

Furthermore, computing device 200 may include controller 212 coupled to chassis detection circuit 210 to detect the chassis type based on the received first and second signals. As shown in FIG. 2A, controller 212 and chassis detection circuit 210 may be disposed on circuit board 202. In one example, controller 212 may control an operating parameter of computing device 200 based on the chassis type. Example operating parameter may be a fan speed.

Example controller 212 and chassis detection circuit 210 may be embedded controllers, which may be implemented in hardware, machine-readable instructions, or a combination thereof. For example, controller 212 and chassis detection circuit 210 may be implemented as engines or modules including any combination of hardware and programming to implement the functionalities described herein. For example, controller 212 and chassis detection circuit 210 can be implemented with microcontrollers, application-specific integrated circuits (ASICs), field programmable gate arrays (FPGAs), or the like. The functions of controller 212 and chassis detection circuit 210 may also be implemented by a processor. In examples described herein, the processor may include, for example, one processor or multiple processors included in a single device or distributed across multiple devices.

FIG. 2B is a schematic view of example computing device 200 of FIG. 2A, depicting an example installation of circuit board 202 within chassis 206. Similarly named elements of FIG. 2B may be similar in function and/or structure to elements described in FIG. 2A. As shown in FIG. 2B, first contact pad 204A may electrically contact grounded circuit board holder 208 when circuit board 202 is installed onto chassis 206. In this example, the voltage level at the input of controller 212 may be pulled to approximately zero volts, Therefore, chassis detection circuit 210 may generate a low-level signal “0”.

Further, second contact pad 204B may not contact any of circuit board holders 208 and 252A-252C and hence the voltage level at the input of controller 212 may be at approximately VCC. In this example, chassis detection circuit 210 may generate a high-level signal “1”. Therefore, controller 212 may receive signals “01” from contact pads 204A and 204B and detect the type of chassis 206.

In the example shown in FIG. 2B, circuit board holders 208 and 252A-252C may be used to align circuit board 202 within chassis 206 by placing circuit board 202 in an aligned orientation within chassis 206. As shown in FIG. 2B, circuit board holder 208 may include a guide member 260 extending perpendicularly from chassis 206 to guide circuit board 202 into the defined position while engaging a side surface of circuit board 202. Further, circuit board holder 208 may include a retaining member 262 extending perpendicularly from guide member 260. In this example, retaining member 262 may include an exposed surface on which a lower surface of the edge of circuit board 202 rests when circuit board 202 is installed onto chassis 206.

Further, appropriate connections, both electrical and mechanical, between circuit board 202 and various elements of chassis 206 may be made and then circuit board 202 may be retained in place with screws, clamps, springs clips and/or other fastening components. In the example shown in FIG. 2B, circuit board 202 may be attached to chassis 206 using a screw 258, i.e., by connecting screw 258 to a receiving feature 254 of chassis 206 through an opening 256 in circuit board 202.

FIG. 2C is a schematic view of example computing device 200 of FIG. 2A, depicting another example installation of circuit board 202 within chassis 206. Similarly named elements of FIG. 2C may be similar in function and/or structure to elements described in FIG. 2A. As shown in FIG. 2C, first contact pad 204A may electrically contact grounded circuit board holder 208 and second contact pad 2048 may not contact any of circuit board holders 208, and 252A-252C when circuit board 202 is installed onto chassis 206.

In the example shown in FIG. 2C, circuit board holder 208 may include a hook structure extending perpendicularly from a base of chassis 206. The hook structure may be engaged with the edge of circuit board 202 to secure circuit board 202 when the hook structure is in a first position. In one example, circuit board holder 208 may contact first contact pad 204A in the first position. The hook structure may be disengaged from circuit board 202 when the hook structure is in a second position. For example, the hook structure may include a vertical guide and retention assembly extending from the base of chassis 206 and guiding circuit board 202 into the defined position while concurrently engaging an upper surface and a lower surface of circuit board 202 thereby restraining circuit board 202 from substantial displacement in a vertical direction. Multiple such hook structures (e.g., 208 and 252B) may be used to restrain circuit board 202 from substantial displacement in a horizontal direction.

Thus, circuit board holder 208 may provide a screwless engagement of circuit board 202 and chassis 206 while contacting contact pad 208 to detect the chassis type. Examples described herein may be implemented using structures that engage the edge of circuit board 202 such as guide members, retaining members, hook structures, and/or any combinations thereof such that different structures may contact different pads to detect the chassis type.

In some examples, circuit board holders that includes a combination of guide and retention members (e.g., to align the circuit board in a prescribed orientation parallel to a base the chassis) and hook structures (e.g., to prevent the circuit board from substantial displacement in lateral and/or vertical directions during and after the installation of the circuit board) can be used to short the contact pads and detect the chassis type.

FIG. 2D is a block diagram of example computing device 200 of FIG. 2A, depicting additional features. Similarly named elements of FIG. 2D may be similar in function and/or structure to elements described in FIG. 2A, As shown in FIG. 2D, chassis detection circuit 210 may include a first pull up resistor 272 having a first end electrically coupled to a voltage source 278 and controller 212. Further, first pull up resistor 272 may have a second end electrically coupled to first contact pad 204A. Also, chassis detection circuit 210 may include a second pull up resistor 274 having a first end electrically coupled to voltage source 278 and controller 212. Further, second pull up resistor 274 may include a second end electrically coupled to second contact pad 204B.

In the example shown in FIG. 2D, the first end of first pull up resistor 272 and second pull up resistor 274 may be coupled to voltage source 278 via a third pull up resistor 276. The first signal and the second signal may depend on a voltage level of the second end of first pull up resistor 272 and second pull up resistor 274, respectively,

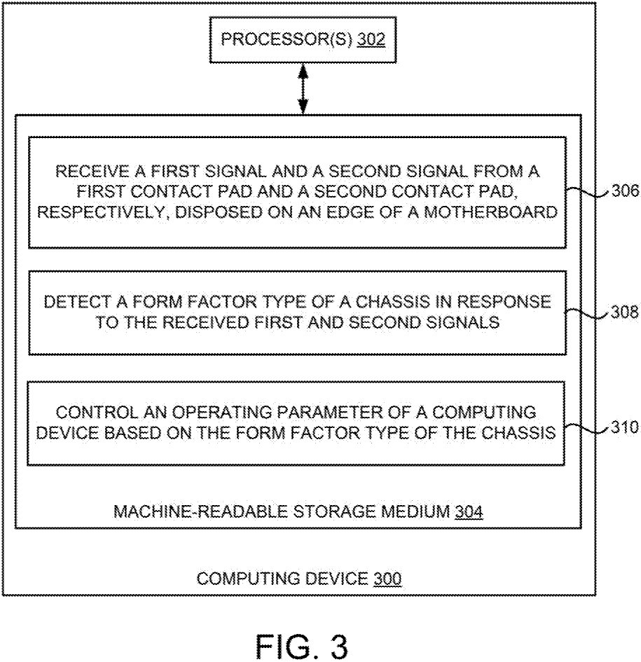

FIG. 3 is a block diagram of an example computing device 300 including a non-transitory machine-readable storage medium 304, storing instructions (e.g., 306 to 310) to control an operating parameter of computing device 300. Computing device 300 may include a processor 302 and machine-readable storage medium 304 communicatively coupled through a system bus. Processor 302 may be any type of central processing unit (CPU), microprocessor, or processing logic that interprets and executes machine-readable instructions stored in machine-readable storage medium 304. Machine-readable storage medium 304 may be a random -access memory (RAM) or another type of dynamic storage device that may store information and machine-readable instructions that may be executed by processor 302, For example, machine-readable storage medium 304 may be synchronous DRAM (SDRAM), double data rate (DDR), rambus DRAM (RDRAM), rambus RAM, etc., or storage memory media such as a floppy disk, a hard disk, a CD-ROM, a DVD, a pen drive, and the like, In an example, machine-readable storage medium 304 may be a non-transitory machine-readable medium. In an example, machine-readable storage medium 304 may be remote but accessible to computing device 300.

As shown in FIG. 3, machine-readable storage medium 304 may store instructions 306-310, In an example, instructions 306-310 may be executed by processor 302 to detect a form factor type of the chassis and control an operating parameter of computing device 300 based on the form factor type of the chassis, instructions 306 may be executed by processor 302 to receive a first signal and a second signal from a first contact pad and a second contact pad, respectively, disposed on an edge of a motherboard in response to the motherboard being installed in a chassis having a form factor type.

The first and second signals may be generated by the first and second contact pads, respectively, based on an interaction with at least one circuit board holder of the chassis that retains the motherboard in a defined position relative to the chassis. Instructions 308 may be executed by processor 302 to detect the form factor type of the chassis in response to the received first and second signals. For example, instructions to detect the form factor type of the chassis may include instructions to detect a type of the computing device in response to the received first and second signals.

In one example, instructions to detect the form factor type of the chassis may include instructions to:
detect the form factor type of the chassis as a first type when the circuit board holder contacts the first contact pad disposed at the edge of the motherboard, and
detect the form factor type of the chassis as a second type when the circuit board holder contacts the second contact pad disposed at the edge of the motherboard,

In another example, instructions to detect the form factor type of the chassis may include instructions to:
detect the form factor type of the chassis as a first type when a first circuit board holder of the chassis contacts the first contact pad and a second circuit board holder of the chassis contacts the second contact pad, and
detect the form factor type of the chassis as a second type when the first circuit board holder contacts the first contact pad and the second circuit board holder contacts a third contact pad of the motherboard,

Instructions 308 may be executed by processor 302 to control an operating parameter of the computing device based on the form factor type of the chassis. For example, the first signal and the second signal may be received from the first contact pad and the second contact pad via traces of a circuit on the circuit board.

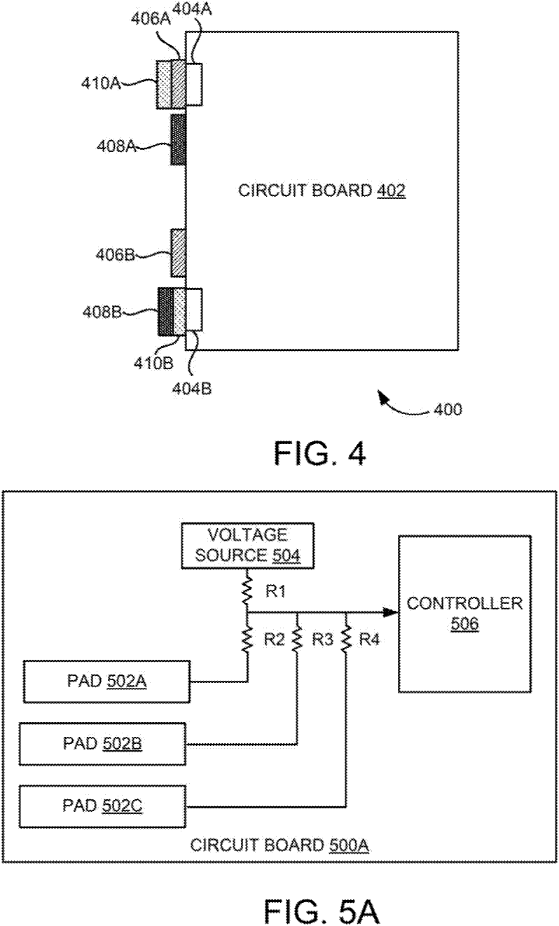

FIG. 4 illustrates a block diagram of an example computing device 400 including circuit board 402 having first and second contact pads 404A and 404B engaging with different circuit board holders on different chassis types. For example, computing device 400 may include a chassis having at least one circuit board holder to hold an edge of circuit board 402 in a defined position relative to the chassis. Different chassis may have circuit board holders located at different positions to assemble circuit board 402 in a defined location. The number and/or chassis locations of the circuit board holders can be unique to a form factor type of the chassis. The circuit board holders may be connected to ground. Further, circuit board 402 may include contact pads 404A and 404B (e.g., copper pads) at an edge of circuit board 402. When circuit board 402 is installed onto the chassis, at least one of contact pads 404A and 404B can be short to ground via contacting the circuit board holder to determine the chassis type.

Consider that circuit board 402 having contact pads 404A and 404B may be installed on 3 different types of chassis (e.g., chassis 1, chassis 2, and chassis 3), each having a pair of corresponding circuit board holders. An example to determine the chassis type with contact pads 404A and 404B is explained with respect to FIG. 4 as follows:
1. Circuit board holder 406A on the chassis 1 may be in contact with contact pad 404A of circuit board 400 and circuit board holder 406B on the chassis 1 may not be in contact with contact pad 404B. In this case, circuit board 402 may generate GPI signals as “01” to identify the chassis 1 as a first type.
2. Circuit board holder 408A, on the chassis 2 may not be in contact with contact pad 404A and circuit board holder 408B on the chassis 2 may be in contact with contact pad 404B. In this case, circuit board 402 may generate GPI signals as “10” to identify the chassis 2 as a second type.
3. Both circuit board holders 410A and 410B of the chassis 3 may be in contact with contact pads 404A and 404B, respectively. In this case, circuit board 402 may generate GPI signals as “00” to identify the chassis 3 as a third type.

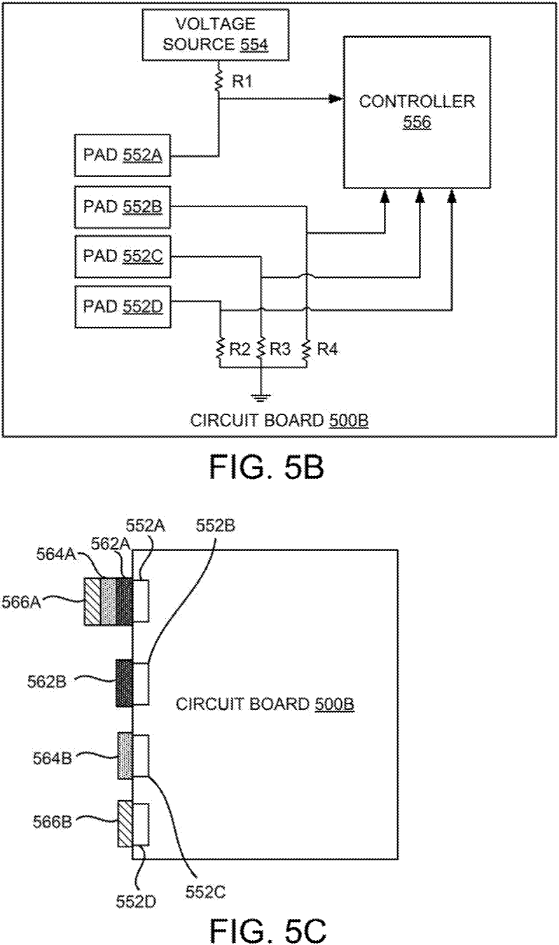

FIG. 5A illustrates a schematic representation of an example circuit board 500A having contact pads 502A, 502B, and 502C, with different contact pads engaging with circuit board holders on different chassis types. In the example shown in FIG. 5A, contact pads 502A, 502B, and 502C may be connected to voltage source 504 and controller 506 through resistors R2, R3, and R4, respectively. One end of resistors R2, R3, and R4 may be connected to contact pads 502A, 502B, and 502C, respectively, Another end of resistors R2, R3, and R4 may be connected to controller 506 and a first end of resistor R1, Second end of resistor R1 may be connected to voltage source 504.

Further, different chassis may have grounded circuit board holders at different locations such that a circuit board holder on a chassis may contact one contact pad at a time (i.e., circuit board holders on one chassis may not contact multiple contact pads at the same time). In other words, contact pad 502A may contact a circuit board holder in a first type of chassis, contact pad 502B may contact a circuit board holder in a second type of chassis, and contact pad 502C may contact a circuit board holder in a third type of chassis.

FIG. 5B illustrates a schematic representation of another example circuit board 500B having contact pads 552A, 552B, 552C, and 552D, with different contact pads engaging with a pair of circuit board holders on different chassis types. In the example shown in FIG. 5B, contact pads 552A, 552B, 552C, and 552D may be connected to voltage source 554 and controller 556 through resistors R1, R4, R3, and R2, respectively, Further, different chassis may have a first circuit board holder at a fixed location and other circuit holders at different locations such that each chassis may have the first circuit board holder at the fixed location to engage with contact pad 552A along with another circuit board holder contacting another contact pad 552B, 552C, or 552D at a same time as shown in FIG. 5C.

FIG. 5C illustrates a block diagram of example circuit board 500B of FIG. 5B, depicting contact pads 552A-552D engaging with different circuit board holders on different chassis types. In other words, contact pads 552A and 552B may contact circuit board holders 562A and 562B in a first type of chassis, contact pads 552A and 552C may contact circuit board holders 564A and 564B in a second type of chassis, and contact pads 552A and 552D may contact circuit board holders 566A and 566B in a third type of chassis. In this example, circuit board holder 562A, 564A, and 566A may be disposed at a common location on different types of chassis such that different chassis types can short contact pad 552A along with one other contact pad 552B, 552C, or 552D by a different circuit board holder or different chassis part.

It may be noted that the above-described examples of the present solution are for the purpose of illustration only. Although the solution has been described in conjunction with a specific implementation thereof, numerous modifications may be possible without materially departing from the teachings and advantages of the subject matter described herein. Other substitutions, modifications and changes may be made without departing from the spirit of the present solution. All of the features disclosed in this specification (including any accompanying claims, abstract, and drawings), and/or all of the steps of any method or process so disclosed, may be combined in any combination, except combinations where at least some of such features and/or steps are mutually exclusive.

The terms “include,” “have,” and variations thereof, as used herein, have the same meaning as the term “comprise” or appropriate variation thereof. Furthermore, the term “based on”, as used herein, means “based at least in part on.” Thus, a feature that is described as based on some stimulus can be based on the stimulus or a combination of stimuli including the stimulus.

The present description has been shown and described with reference to the foregoing examples. It is understood, however, that other forms, details, and examples can be made without departing from the spirit and scope of the present subject matter that is defined in the following claims.

What is claimed is:

1. A computing device comprising:
a circuit board having a contact pad disposed at an edge of the circuit board;
a chassis in which the circuit board is installed, wherein the chassis comprises:
a circuit board holder to engage the edge of the circuit board to retain the circuit board in a defined position relative to the chassis, wherein the circuit board holder is grounded; and
a controller to:
receive a signal from the contact pad, the signal indicative of a contact between the circuit board holder and the contact pad; and
detect a form factor type of the chassis based on the received signal.

2. The computing device of claim 1, wherein the circuit board holder comprises:
a guide member extending perpendicularly from the chassis to guide the circuit board into the defined position while engaging a side surface of the circuit board; and
a retaining member extending perpendicularly from the guide member, wherein the retaining member comprises an exposed surface on which a lower surface of the edge of the circuit board rests when the circuit board is installed onto the chassis.

3. The computing device of claim 1, wherein the contact pad is a copper pad.

4. The computing device of claim 1, further comprising:
a pull up resistor having a first end electrically coupled to a voltage source and a second end electrically coupled to the contact pad, wherein the signal is to depend on a voltage level of the second end, and wherein the contact pad is connected to the controller.

5. The computing device of claim 1, wherein the controller is to control a parameter of the computing device that is dependent on the form factor type of the chassis.

6. A computing device comprising:
a circuit board having a first contact pad and a second contact pad disposed at an edge of the circuit board;
a chassis in which the circuit board is installed, the chassis is of a chassis type, wherein the chassis comprises:
a circuit board holder to hold the circuit board in a defined position relative to the chassis, wherein the circuit board holder is grounded;
a chassis detection circuit to generate a first signal and a second signal when the circuit board is engaged with the chassis, wherein the first and second signals are indicative of an electrical contact between the grounded circuit board holder and one of the first contact pad and the second contact pad; and
a controller coupled to the chassis detection circuit to detect the chassis type based on the received first and second signals.

7. The computing device of claim 6, wherein the circuit board holder comprises:
a guide member extending perpendicularly from the chassis to guide the circuit board into the defined position while engaging a side surface of the circuit board; and
a retaining member extending perpendicularly from the guide member, wherein the retaining member comprises an exposed surface on which a lower surface of the edge of the circuit board rests when the circuit board is installed onto the chassis.

8. The computing device of claim 6, wherein the circuit board holder comprises:
a hook structure extending perpendicularly from the chassis,
wherein the hook structure is engaged with the edge of the circuit board to secure the circuit board when the hook structure is in a first position, wherein the circuit board holder is to contact one of the first contact pad and the second contact pad in the first position, and
wherein the hook structure is disengaged from the circuit board when the hook structure is in a second position.

9. The computing device of claim 6, wherein the controller is to control an operating parameter of the computing device based on the chassis type, and wherein the operating parameter is a fan speed.

10. The computing device of claim 6, wherein the controller and the chassis detection circuit are disposed on the circuit board.

11. The computing device of claim 6, wherein the chassis detection circuit comprises:
a first pull up resistor comprising:
a first end electrically coupled to a voltage source and the controller; and
a second end electrically coupled to the first contact pad; and
a second pull up resistor comprising:
a first end electrically coupled to the voltage source and the controller; and
a second end electrically coupled to the second contact pad, wherein the first signal and the second signal depend on a voltage level of the second end of the first pull up resistor and the second pull up resistor, respectively.

12. A non-transitory machine-readable storage medium encoded with instructions that, when executed by a processor of a computing device, cause the processor to:
receive a first signal and a second signal from a first contact pad and a second contact pad, respectively, disposed on an edge of a motherboard in response to the motherboard installed in a chassis having a form factor type, the first and second signals are generated by the first and second contact pads, respectively, based on an interaction with at least one circuit board holder of the chassis that retains the motherboard in a defined position relative to the chassis; and
detect the form factor type of the chassis in response to the received first and second signals; and
control an operating parameter of the computing device based on the form factor type of the chassis.

13. The non-transitory machine-readable storage medium of claim 12, wherein instructions to detect the form factor type of the chassis comprises instructions to:
detect the form factor type of the chassis as a first type when the circuit board holder contacts the first contact pad disposed at the edge of the motherboard; and
detect the form factor type of the chassis as a second type when the circuit board holder contacts the second contact pad disposed at the edge of the motherboard.

14. The non-transitory machine-readable storage medium of claim 12, wherein instructions to detect the form factor type of the chassis comprises instructions to:
detect the form factor type of the chassis as a first type when a first circuit board holder of the chassis contacts the first contact pad and a second circuit board holder of the chassis contacts the second contact pad; and
detect the form factor type of the chassis as a second type when the first circuit board holder contacts the first contact pad and the second circuit board holder contacts a third contact pad of the motherboard.

15. The non-transitory machine-readable storage medium of claim 12, wherein instructions to detect the form factor type of the chassis comprises instructions to:
detect a type of the computing device in response to the received first and second signals.
